(19) United States
(12) Patent Application Publication
(10) Pub. No.: US 2006/0237807 A1
(43) Pub. Date: Oct. 26, 2006

(54) Electro-optic transducer die including a temperature sensing PN junction diode

(76) Inventor: Lucy G. Hosking, Santa Cruz, CA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/110,112

(22) Filed: Apr. 20, 2005

(51) Int. Cl. H01L 43/00; H01L 29/82

(52) U.S. Cl. 257/421

(57) ABSTRACT

An electro-optic transducer die that includes both an optically emissive PN junction diode and a temperature sensing PN junction diode. Since the temperature sensing PN junction diode is in the very same die as the optically emissive PN junction diode, there is very little thermal resistance between the optically emissive PN junction diode and the temperature sensing PN junction diode. Accordingly, the temperature sensed by the temperature sensing PN junction diode more accurately tracks the actual temperature of the optically emissive PN junction diode.

### BACKGROUND OF THE RELATED ART

1. The Field of the Invention

The present invention relates generally to optical transmitters. More specifically, the present invention relates to an electro-optic transducer die that includes a temperature sensing PN junction diode, in addition to the optically emissive PN junction diode.

2. Background and Related Art

Computing and networking technology have transformed our world. As the amount of information communicated over networks has increased, high speed transmission has become ever more critical. Many high speed data transmission networks rely on optical transceivers and similar devices for facilitating transmission and reception of digital data embodied in the form of optical signals over optical fibers. Optical networks are thus found in a wide variety of high speed applications ranging from as modest as a small Local Area Network (LAN) to as grandiose as the backbone of the Internet.

Typically, data transmission in such networks is implemented by way of an optical transmitter (also referred to as an optically emissive PN junction diode), such as a laser diode or Light Emitting Diode (LED). The optically emissive PN junction diode emits light when current is passed through it, the intensity of the emitted light being a function of the current magnitude being passed through the optically emissive PN junction diode. Information is conveyed optically by the optically emissive PN junction diode transmitting different optical intensities.

The optical emission frequencies from the optically emissive PN junction diode have strong temperature dependencies that can seriously affect performance, depending on the application. For example, in Dense Wavelength Division Multiplexed (DWDM) laser applications, different optical channels are transmitted simultaneously, each optical channel having a tight frequency range that the corresponding optical signal should stay within. Any variance outside of the frequency range could cause inter-signal interference, seriously increasing the error rate of the transmission. Thus, in DWDM laser applications, it is critical that the laser's transmitted frequency be tightly controlled. Nevertheless, the frequency characteristics of the emitted light from the optically emissive PN junction diode are heavily temperature-dependent. Although DWDM has been discussed here, there are a wide variety of applications in which it may be desirable to accurately control the temperature of the optically emissive PN junction diode.

The temperature control of the optically emissive PN junction diode typically relies on a temperature feedback system. Specifically, a temperature sensor is provided in proximity to the optically emissive PN junction diode. Depending on the sensed temperature, a temperature driver then heats or cools the temperature sensor as appropriate until the temperature sensor detects a temperature within an acceptable temperature range. The aim here is that by tightly controlling the temperature of the temperature sensor, the temperature of the proximate optically emissive PN junction diode will also be tightly controlled.

However, the temperature sensor and the electro-optic transducer junction cannot occupy the same space at the same time. Therefore, the temperature sensor, though relatively close to the optically emissive PN junction diode, is still placed some finite distance from the optically emissive PN junction diode. There will thus be some finite amount of thermal resistance between the temperature sensor and the optically emissive PN junction diode.

The temperature of the optically emissive PN junction diode may vary significantly as the optically emissive PN junction diode itself generates heat. Furthermore, the temperature sensor may also generate heat. In addition, the temperature sensor and the optically emissive PN junction diode may dynamically exchange heat with other surrounding components and the environment. Thus, due to the thermal resistance between the temperature sensor and the electro-optic transducer, there will be some error between the temperature sensed by the temperature sensor and the actual temperature of the optically emissive PN junction diode. In this way, even very tight control of the temperature of the temperature sensor, will not necessarily result in tight control of the temperature of the optically emissive PN junction diode.

Accordingly, what would be advantageous are mechanisms in which there is tighter control of the temperature of the optically emissive PN junction diode.

### BRIEF SUMMARY OF THE INVENTION

The foregoing problems with the prior state of the art are overcome by the principles of the present invention, which relate to an electro-optic transducer die that includes both an optically emissive PN junction diode configured to emit optical signals when electricity is passed through the optically emissive PN junction diode, and a temperature sensing PN junction diode configured to provide a signal that varies with temperature. Due to the extremely close proximity of the optically emissive PN junction diode and the temperature sensing PN junction diode (being within the same die), the thermal resistance between the optically emissive PN junction and the temperature sensing PN junction diode is reduced. Accordingly, the temperature detected by the temperature sensing PN junction diode more closely tracks the actual temperature of the optically emissive PN junction diode.

The highly accurate temperature measurements allow for tight temperature control of the optically emissive PN junction thereby more tightly controlling the frequency of the optical emissions from the optically emissive PN junction. The tight control of frequency, in turn, reduces the risk of inter-signal interference in DWDM communication systems, and may even permit the frequency span of a given optical channel in a frequency division multiplexed environment to be even further reduced in future standards, thereby potentially increasing the possible optical data rate.

Additional features and advantages of the invention will be set forth in the description that follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features of the invention can be obtained, a more particular description of the invention briefly described above will be rendered by reference to specific embodiments thereof which are illustrated in the appended drawings. Understanding that these drawings depicts only an example embodiment of the invention and is not therefore to be considered to be limiting of its scope, the invention will be described and explained with additional specificity and detail through the use of the accompanying drawing in which:

FIG. 1 illustrates a top view of an electro-optic transducer die, which includes both an optically emissive PN junction diode, and a temperature sensing PN junction diode; and

FIG. 2 illustrates a profile view of the electro-optic transducer die of FIG. 1 mounted on a substrate and further being coupled to a temperature driver and heat sink.

### DETAILED DESCRIPTION OF THE PREFERRED EMBODIMENTS

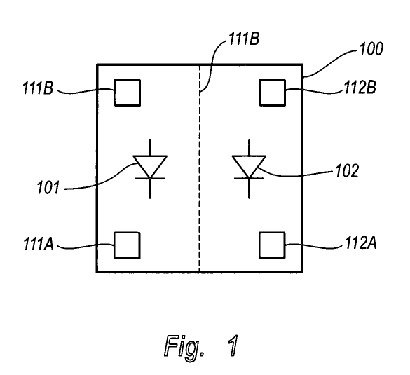

FIG. 1 illustrates a top view of an electro-optic transducer die 100 in accordance with the principles of the present invention. The electro-optic transducer die 100 includes both an optically emissive PN junction diode as symbolically represented using diode symbol 101, and a temperature sensing PN junction diode as symbolically represented using diode symbol 102. Since the temperature sensing PN junction diode 102 is in the very same die as the optically emissive PN junction diode 101, there is very little thermal resistance between the optically emissive PN junction diode 101 and the temperature sensing PN junction diode 102. Accordingly, the temperature sensed by the temperature sensing PN junction diode 102 more accurately tracks the actual temperature of the optically emissive PN junction diode 101. The temperature of the optically emissive PN junction diode 101 may thus be more tightly controlled, which is particularly advantageous in environments in which temperature variations of the optically emissive PN junction diode may change the optical output wavelength, as in, for example, Dense Wavelength Division Multiplexing (DWDM) applications.

Referring to FIG. 1, the optically emissive PN junction 101 may be a laser diode or a Light-Emitting Diode (LED). If a laser, there is no restriction on the type of laser. Examples of lasers include edge-emitting lasers, Vertical Cavity Surface Emitting Lasers (VCSELs), and others. There are two electrical contacts 111A and 111B patterned in the electro-optic transducer die 100 for applying a control current through the optically emissive PN junction diode 101 to thereby control optical emissions from the diode 101. Of course, depending on the type of the electro-optic transducer, more or fewer electrical connections 111 may be warranted.

The temperature sensing PN junction diode 102 may be any PN junction temperature sensing device. PN junction diodes all assert a voltage drop on current that passes through a PN junction. The precise magnitude of the voltage drop has strong temperature dependencies. Accordingly, by measuring the voltage drop through the temperature sensing PN junction diode 102, the corresponding temperature at the diode 102 may be determined. There are two electrical contacts 112A and 112B patterned in the electro-optic transducer die 100 for applying a control current through the temperature sensing PN junction diode 101 to thereby measure the voltage drop (and thus the temperature) of the temperature sensing PN junction diode.

In order to ensure that the operation of the optically emissive PN junction diode 101 is not adversely affected by the operation of the temperature sensing PN junction diode 102, a barrier is placed between the two diodes as represented symbolically using dashed line 110. This barrier 110 may serve as an electrical barrier to avoid electrical interference between the two diodes. Such an electrical barrier may be achieved by inserting a low conductivity material such as glass between the two diodes, or perhaps by doping a region between the two diodes such that current cannot easily pass from one diode region to the other diode region. The barrier 110 may also serve as an optical barrier to protect against the optics from one diode adversely affecting the performance of the other diode. The optical barrier may be achieved using any appropriately structured optical barrier. The optical barrier 110 may be achieved using a single structure that serves as both an optical and electrical barrier. Furthermore, the optical barrier 110 may be achieved using structures within the die itself. For instance, the temperature sensing PN junction diode may be fabricated so that the temperature sensing diode is neither affected by light emitting from the optically emissive PN junction diode, nor emits interfering light into the optical emissive PN junction diode.

The temperature sensing PN junction diode 102 may be closely positioned to the optically emissive PN junction diode 101 since both diodes are within the body of the same electro-optic transducer die. Processing technology allows the diodes 101 and 102 to be placed in extremely close proximity to each other. Accordingly, the thermal resistance between the temperature sensing PN junction diode 102 and the optically emissive PN junction diode 101 is reduced. Accordingly, the more closely-positioned temperature sensing PN junction diode 102 more accurately measures the temperature of the optically emissive PN junction diode 101. Thus, the temperature and emitted frequencies of the optically emissive PN junction diode 101 may be more finely controlled.

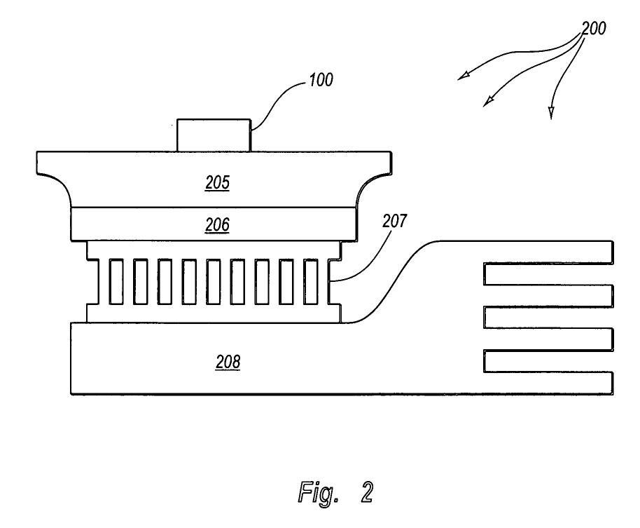

FIG. 2 illustrates a profile view of the electro-optic transducer die 100 of FIG. 1 mounted on a substrate 205 for structural support. A thermo-electric cooler 207 is thermally coupled to the substrate 205. In order to allow uniform heat transfer with the lower surface of the substrate 205, a thermally conductive piece 206 may be positioned between the thermoelectric cooler 207 and the substrate 205. A heat sink 208 is thermally coupled to the thermo-electric cooler 207.

Accordingly, the principles of the present invention provide an electro-optic transducer die in which the temperature (and thus the frequency) of the optically emissive PN junction diode may be tightly controlled. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes, which come within the meaning and range of equivalency of the claims, are to be embraced within their scope.

What is claimed and desired secured by United States Letters Patent is:

1. An electro-optic transducer die comprising:
an optically emissive PN junction diode configured to emit optical signals when electricity is passed through the optically emissive PN junction diode; and
a temperature sensing PN junction diode configured to provide a signal that varies with temperature.

2. An electro-optic transducer die in accordance with claim 1, further comprising:
an electrical barrier configured between the optically emissive PN junction diode and the temperature sensing PN junction diode.

3. An electro-optic transducer die in accordance with claim 1, further comprising:
an optical barrier configured between the optically emissive PN junction diode and the temperature sensing PN junction diode.

4. An electro-optic transducer die in accordance with claim 3, further comprising:
an electrical barrier configured between the optical emissive PN junction diode and the temperature sensing PN junction diode.

5. An electro-optic transducer die in accordance with claim 4, wherein the optical barrier and the electrical barrier are the same structure.

6. An electro-optic transducer die in accordance with claim 1, wherein the electro-optic transducer die is mounted on a substrate that is coupled to a temperature driver.

7. An electro-optic transducer die in accordance with claim 1, wherein the optically emissive PN junction diode is a laser diode.

8. An electro-optic transducer die in accordance with claim 1, wherein the optically emissive PN junction diode is a Light Emitted Diode (LED).

9. An electro-optic transducer die in accordance with claim 1, further comprising:
one or more electrical contacts for forming an electrical connection to the optically emissive PN junction diode; and
one or more electrical contacts for forming an electrical connection to the temperature sensing PN junction diode.

10. A method for manufacturing an electro-optic transducer die comprising:
an act of forming an optically emissive PN junction diode in the electro-optic transducer die, wherein the optically emissive PN junction diode is configured to emit optical signals when electricity is passed through the optically emissive PN junction diode; and
an act of forming a temperature sensing PN junction diode in the electro-optic transducer die, wherein the temperature sensing PN junction diode is configured to provide a signal that varies with temperature.

11. A method in accordance with claim 10, further comprising:
an act of placing an electrical barrier between the optically emissive PN junction diode and the temperature sensing PN junction diode.

12. A method in accordance with claim 11, further comprising:
an act of placing an optical barrier between the optically emissive PN junction diode and the temperature sensing PN junction diode.

13. A method in accordance with claim 12, wherein the electrical barrier and the optical barrier are part of the same structure such that the acts of placing the electrical barrier and placing the optical barrier occur simultaneously.

14. A method in accordance with claim 10, further comprising:
an act of placing an optical barrier between the optically emissive PN junction diode and the temperature sensing PN junction diode.

15. A method in accordance with claim 10, further comprising:
an act of forming one or more electrical contacts on the electro-optic transducer die to form an electrical connection to the optically emissive PN junction diode; and
an act of forming one or more electrical contacts on the electro-optic transducer die to form an electrical connection to the temperature sensing PN junction diode.
